(19) United States
(12) Patent Application Publication
(10) Pub. No.: US 2010/0291489 A1
(43) Pub. Date: Nov. 18, 2010

(54) EXPOSURE METHODS FOR FORMING PATTERNED LAYERS AND APPARATUS FOR PERFORMING THE SAME

(75) Inventors: Martin Moskovits, Santa Barbara, CA (US); Linh Nguyen, Allentown, PA (US); Robert Koefer, Whitehall, PA (US); Qihong Wu, Somerset, NJ (US); Xu Zhang, Montville, NJ (US); Shiaw-Wen Tai, Livingston, NJ (US)

Correspondence Address: RATNERPRESTIA, P.O. BOX 980, VALLEY FORGE, PA, 19482, US

(73) Assignee: API Nanofabrication and Research Corp., Somerset, NJ (US)

(21) Appl. No.: 12/466,853

(22) Filed: May 15, 2009

(51) Int. Cl. G03F 7/20

(52) U.S. Cl. 430/323; 430/322; 430/325; 430/326

(57) ABSTRACT

Methods include providing an article including a substrate, a first layer supported by the substrate, and an interface between the substrate and the first layer. The substrate is substantially transparent to radiation at a wavelength λ and the first layer is formed from a photoresist. The methods include exposing the first layer to radiation by directing radiation at λ through the substrate to impinge on the interface so that the radiation experiences total internal reflection at the interface.

### BACKGROUND

Photolithography refers to technique used commonly used to formed patterned layers in, for example, the manufacture of integrated circuits. Generally, photolithography involves exposing a photo-sensitive material, such as photo-resist, to patterned radiation to form a pattern in the photo-sensitive material. Subsequent processing, including developing the exposed photo-sensitive material and etching an underlying layer or depositing material onto the developed photo-sensitive material, transfers the pattern in the photo-sensitive material to a layer from which an integrated circuit is composed.

A variety of different techniques can be used to provide patterned radiation to a photoresist layer. For example, projection lithography involves using an optical imaging system to project an image of a patterned reticle onto a layer of photoresist. Another example is holographic lithography, which involves exposing a resist layer to an interference pattern formed by overlapping coherent beams of radiation on the surface of the photoresist.

In both projection lithography and holographic lithography, liquid immersion techniques can be used to advantageously decrease the smallest feature size of the patterned radiation. In projection lithography, for example, liquid immersion is used to provide optical imaging systems with extremely high numerical apertures, allowing for very high resolution imaging. In holographic lithography, liquid immersion can be used to allow for high incident angles of interfering radiation beams at the resist, facilitating interference patterns with high intensity in the resist and small pitch.

### SUMMARY

This disclosure relates generally to methods and systems of exposing articles to patterned radiation. More specifically, the disclosure features techniques for exposing a photoresist layer supported by a substrate to patterned radiation by exposing the photoresist layer through the substrate. Rather than expose the photoresist directly with the radiation through the substrate, the techniques involves total internal reflection of the exposing radiation at an interface between the photoresist layer and the surface of the substrate opposite the photoresist layer so that the photoresist is exposed to an evanescent radiation field. This exponentially decaying radiation field exposes the photoresist layer to a patterned field, after which the exposed photoresist layer can be processed as for a conventional exposure.

In general, the patterned radiation is formed by interfering two or more beams at the substrate. The interfering beams can be coupled into the substrate at high angles using, for example, a prism optically coupled to the substrate using an index-matching fluid. In other words, the photoresist layer can be exposed to interference patterns formed by beams having high angles of incidence with respect to the plane of the substrate, but without having to immerse the photoresist in a liquid to enable the high angles of incidence.

Thus, common drawbacks associated with immersing a photoresist with an index-matching liquid, such as leaching of chemicals into or liquid contamination of the photoresist layer, can be avoided. Defects left by immersion fluids that have dried on the photo-sensitive layer also can be eliminated.

Among other advantages, the techniques can be implemented without a mask or reticle, which can be extremely expensive and typically involve complex positioning systems to control their location relative to the substrate during exposure.

The disclosed methods and systems can be applied to lithographic patterning stages in the manufacture of integrated circuits, components and optical elements, among other devices. For example, in some embodiments, the evanescent wave exposure can be used to produce gratings for monochromators, spectrometers, wavelength division multiplexing devices and other electromagnetic modifying devices.

In general, in one aspect, the invention features methods that include providing an article including a substrate, a first layer supported by the substrate, and an interface between the substrate and the first layer. The substrate is substantially transparent to radiation at a wavelength λ and the first layer is formed from a photoresist. The methods include exposing the first layer to radiation by directing radiation at λ through the substrate to impinge on the interface so that the radiation experiences total internal reflection at the interface.

Implementations of the methods can include one or more of the following features and/or features of other aspects. For example, the radiation can form an intensity pattern at the interface. The intensity pattern can be an interference pattern. The interference pattern can be formed by directing a first part of the radiation and a second part of the radiation along different paths to overlap at the interface. The different paths can each impinge on the interface once. In some embodiments, the first part impinges on the interface twice. The interference pattern can be formed by directing a third part of the radiation to overlap with the first and second parts of the radiation at the interface, wherein the third part is directed along a different path to the first and second parts.

Exposing the first layer to radiation can include exposing the layer to the radiation a first time with a first relative orientation between the first layer and the intensity pattern and exposing the layer to the radiation a second time with a second relative orientation between the first layer and the intensity pattern, the first and second relative orientations being different. The methods can include rotating the article prior to exposing the layer to the radiation a second time.

The intensity pattern can be periodic in at least one dimension. For example, the intensity pattern can have a period of about 200 nm or less (e.g., about 150 nm or less, about 120 nm or less, about 100 nm or less) in the at least one dimension.

The radiation can be directed to impinge on the interface at an angle of incidence that is equal to or greater than the critical angle.

In some embodiments, the radiation is directed to impinge on the interface at an angle of incidence that is about 45° or more (e.g., about 60° or more, about 70° or more).

Directing the radiation through the substrate can include directing the radiation through a prism. The prism can be optically coupled to the substrate. The substrate and the prism can have substantially the same refractive index at λ. The article further comprises an index matching fluid between the prism and the substrate.

The substrate can include glass. The substrate can include quartz. The substrate can include fused silica. The substrate can include ruby or sapphire.

The radiation can be substantially collimated while propagating through the substrate.

λ can be about 500 nm or less (e.g., about 300 nm or less). λ can be in a range from 10 nm to about 2,000 nm. λ can be 193 nm, 242 nm, 266 nm, 351 nm, 512 nm, or 1,032 nm.

The substrate can have a refractive index, nₛ, and the photoresist has a refractive index, nᵣ, and nₛ>nᵣ at λ. the substrate can have a refractive index, nₛ, that is about 1.5 or more (e.g., 1.6 or more, 1.7 or more, 1.8 or more, 1.9 or more) at λ.

The interface can be the interface between the substrate and the photoresist of the first layer.

In some embodiments, the article further includes an antireflection coating for radiation at λ.

The method can include forming a pattern in the substrate after exposing the first layer. Forming the pattern can include developing the photoresist after exposing the first layer. Forming the patterning can include etching the substrate after developing the photoresist. Forming the pattern can include depositing a mask material onto the first layer after developing the photoresist. The mask material can be a metal. The mask material can be directionally deposited onto the first layer.

In general, in another aspect, the invention features methods that include providing an article including a substrate and a first layer supported by the substrate, the substrate being substantially transparent to radiation at a wavelength λ and the first layer comprising a photoresist, and exposing the first layer to evanescent radiation by directing radiation at λ through the substrate. Implementations of the methods can include one or more of the features of other aspects.

In general, in another aspect, the invention features methods that include directing radiation at a wavelength λ at an interface between a first layer and a second layer, wherein the radiation is directed at an angle greater than a total internal reflection critical angle such that the second layer is exposed to an evanescent wave, and developing regions of the second layer exposed to the evanescent wave to form a pattern in the second layer.

Implementations of the methods can include one or more of the following features and/or features of other aspects. For example, the radiation can be coupled from the first layer through the second layer to a third layer. The first layer can have a refractive index, n₁, the second layer has a refractive index, n₂, the third layer has a refractive index, n₃, and n₂<n₁, n₃.

In general, in another aspect, the invention features processes for manufacturing a grating pattern that include providing a first layer in contact with a second layer; exposing the second layer to an evanescent interference pattern, wherein exposing the second layer includes directing radiation at wavelength λ towards an interface between the first layer and the second layer such that the radiation is totally internally reflected at the interface, and removing the exposed portions or unexposed portions of the second layer to form the grating pattern.

Implementations of the processes can include one or more of the following features and/or features of other aspects. For example, directing radiation towards the interface can include directing the radiation along a first path and directing the radiation along a second path that is different from the first path. The radiation can include a first electromagnetic wave propagating in a direction transverse to the interface. The radiation can include a second electromagnetic wave propagating in a direction opposite to the first electromagnetic wave.

In some embodiments, a process further includes transferring the grating pattern from the first layer to the second layer.

Other features, and advantages of the invention will be apparent from the description and drawings, and from the claims.

### BRIEF DESCRIPTION OF DRAWINGS

FIG. 1 is a schematic diagram of an embodiment of an apparatus for exposing a target to radiation.

FIG. 2A shows an embodiment of an apparatus for exposing a target to radiation.

FIG. 2B shows the target of FIG. 2A in more detail.

FIG. 3A shows an embodiment for exposing a target to radiation.

FIG. 3B shows an embodiment for exposing a target to radiation.

FIG. 3C shows an embodiment for exposing a target to radiation.

FIG. 3D shows an embodiment for exposing a target to radiation.

FIG. 4 shows an embodiment of a mounting device.

FIG. 5 shows an embodiment of a target on a substrate holder.

FIG. 6 illustrates a process flow for forming a pattern.

FIGS. 7A-7F illustrate an example photolithography process.

FIG. 8 shows an example grating pattern.

FIG. 9 shows an example grating pattern.

FIG. 10 shows an example grating pattern.

FIG. 11 shows an embodiment for exposing a target to radiation.

FIG. 12 shows an embodiment for exposing a target to radiation.

### DETAILED DESCRIPTION

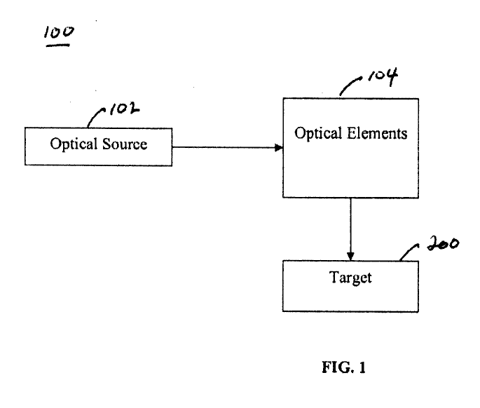

FIG. 1 is a schematic diagram of an apparatus 100 for exposing a target 200 to radiation. Apparatus 100 includes a source 102 to emit radiation, one or more elements 104 to shape, modify or guide the radiation emitted by source 102, and target 200 on which the radiation is incident.

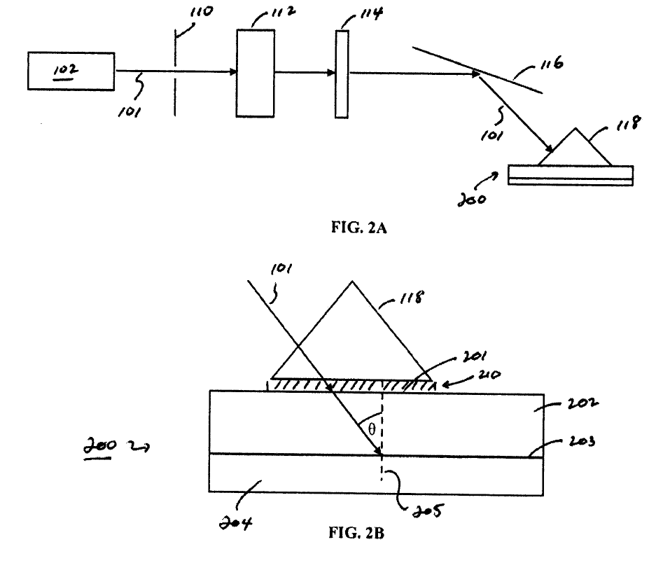

FIG. 2A shows an embodiment of apparatus 100 in more detail. Here, elements 104 include, for example, a shutter 110, a beam expander 112, a polarizer 114, a mirror 116 and a coupling device 118. Radiation 101, having a wavelength λ, is emitted from source 102 in the form of a beam which is directed and/or shaped by elements 104, before being incident on target 200. Specifically, upon exiting polarizer 114, radiation 101 is redirected by mirror 116 towards coupling device 118, which is placed above and/or in contact with target 200. In the embodiment shown in FIG. 2A, coupling device 118 is a prism, although other coupling devices also can be used, as will be described below.

FIG. 2B illustrates the radiation path as it passes through coupling device 118. Coupling device 118 serves to refract incident radiation 101 towards an interface 201 that exists between device 118 and target 200. As shown in the embodiment of FIG. 2B, target 200 includes a substrate 202 and a first layer 204, both of which substantially transmit radiation at wavelength λ. Here, substrate 202 is formed of a material having a refractive index n₁ that closely matches a refractive index nₚ of the prism. Furthermore, a layer of an index-matching fluid 210 having a refractive index close to n₁ and nₚ (e.g., the same as either or both n₁ and nₚ) can be included between the prism and substrate 202. Accordingly, due to index matching, radiation 101 incident on interface 201 can pass into substrate 202 with little or no reflection. Radiation 101 then travels towards a second interface 203 between substrate 202 and first layer 204.

In contrast to substrate 202, first layer 204 is formed of a material having a refractive index n₂, in which n₁>n₂. If the incident angle θ of radiation 101 (as measured with respect to a normal 205 to interface 203) is greater than a critical angle θ_{c}, then radiation 101 is totally internally reflected at the interface 203. The critical angle depends on the refractive index of the first and second layers and is given by: θ_{c}=arcsin(n₂/n₁).

Even though incident radiation 101 is totally internally reflected, there is a portion of incident radiation that penetrates into second layer 204 in the form of an evanescent wave (not shown). The evanescent wave is an electromagnetic field that exponentially decays as it propagates within second layer 204. Accordingly, if second layer 204 is a photo-sensitive material, such as photoresist, it is exposed to the evanescent wave radiation. Thus, where incident radiation 101 has a spatially varying intensity profile at interface 203, the radiation profile, or pattern, can be transferred to second layer 204 using evanescent wave exposure. Based on the type of photo-sensitive material used, second layer 204 then may be developed to remove either the exposed or non-exposed material and reveal the transferred pattern.

In some embodiments, the spatially varying intensity pattern is in the form of an interference pattern. The interference pattern can be periodic in at least one dimension. For example, two beam interference patterns generally have an intensity distribution that is periodic in one direction. The period, II, of the interference pattern can be determined using the equation Π=λ/(2×n₁×sin (Π/2−θ)), where θ is the angle of incidence of radiation 101 as measured with respect to the normal 205 to interface 203. For example, if θ=30°, n₁=1.517, and radiation 101 has a wavelength λ=1032 n₁, the interference 30 pattern has a period of Π≅393 nm.

In general, as indicated by the above equation for Π, Π varies depending on the wavelength λ of optical source 102, the refractive index of the medium in which the beams interfere, n₁, and the relative propagation angles of the interfering beams. Accordingly, to obtain interference patterns with finer periods (i.e., smaller values of Π), radiation 101 having smaller wavelengths can be used. Generally, source 102 is selected to provide radiation at a wavelength that will provide the desired period, and also that will initiate the desired response in the photoresist layer.

Typically, optical sources that emit wavelengths in a range from 10 nm to about 2000 nm may be used. In some embodiments, optical source 102 can be selected to emit radiation in the ultraviolet (UV) portion of the spectrum (e.g., in a range from 10 nm to about 400 nm, such as from about 150 nm to about 300 nm). For example, sources having wavelength equal to 157 nm, 193 nm, 242 nm, 266 nm, or 351 nm can be used. In some embodiments, sources that emit visible radiation can be used (e.g., radiation in a range from about 400 nm to about 700 nm). For example, a source having a wavelength equal to 512 nm can be used.

Typically, source 102 is a coherent source, such as a laser (e.g., a solid state or gas laser), which emits radiation 101 in the form of a beam. More generally, radiation sources other than lasers can also be used. For example, in some embodiments, source 102 is a gas-discharge lamp or an electroluminescent lamp.

Furthermore, in general, elements 104 in apparatus 100 can include additional or fewer optical elements than those shown in FIG. 2A. Generally, elements 104 are used for modifying the shape and/or direction of radiation 101. Such elements can include, for example, lenses, shutters, retarders, diffraction gratings, mirrors, filters, beam-splitters, coupling devices, among others. In certain embodiments, elements 104 deliver a collimated beam having a substantially uniform intensity profile to target 200. Alternatively, in some embodiments, elements 104 can deliver a beam with a predetermined non-uniform intensity profile to target 200, such as a Gaussian profile.

Although coupling device 118 is shown as a triangular shaped coupling prism in FIG. 2A, other coupling devices can be used as well. For example, coupling device 118 could be a semi-circular prism, a quarter-circular prism, a tetrahedron or other polygon shaped coupling device. In some cases, coupling device 118 can be a grating coupler formed in the surface of substrate 202.

In general, coupling device 118 is formed of a material that is similar in refractive index to substrate 202 including, for example, sapphire, glass, quartz, fused silica, or ruby. Other prism coupling material can be used as well.

As explained above, substrate 202 is formed of a material that supports transmission of radiation at wavelength λ and has a refractive index n₁. Material that can be used for substrate 202 includes, but is not limited to, fused silica, glass, sapphire, silicon, quartz, or a polymer (e.g., polyimide or polycarbonate). In general, the refractive index, n₁, of material used for substrate 202 can be about 1.3 or more at λ (e.g., about 1.4 or more at λ, about 1.5 or more at λ, about 1.6 or more at λ, about 1.7 or more at λ, about 1.8 or more at λ, or about 1.9 or more at λ).

First layer 204, which is formed on a surface of substrate 202, also supports transmission of radiation at wavelength λ and can include photo-sensitive material such as positive photoresist, negative photoresist, deep-UV photoresist, or a photo-definable polymer. To allow for total internal reflection at interface 203 between substrate 202 and first layer 204, the material used to form first layer 204 preferably has a refractive index n₂ different from n₁ (e.g., greater than n₁)n₂ can be greater than 1.3 at λ (e.g., about 1.4 or more at λ, about 1.5 or more at λ, about 1.6 or more at λ, about 1.7 or more at λ, about 1.8 or more at λ, or about 1.9 or more at λ).

To achieve total internal reflection at interface 203, the incident angle of radiation 101 with respect to normal 205 should be greater than the critical angle θ_{c}. Depending on the materials selected for substrate 202 and first layer 204, the incident angle can be about 10° or more (e.g., about 20° or more, about 30° or more, about 40° or more, about 50° or more, about 60° or more, about 70° or more). The angle of incidence of radiation 101 can be adjusted using multiple methods such as rotating/translating mirror 116 or rotating/translating the orientation of target 200. Other methods of adjusting the incident angle can be used as well.

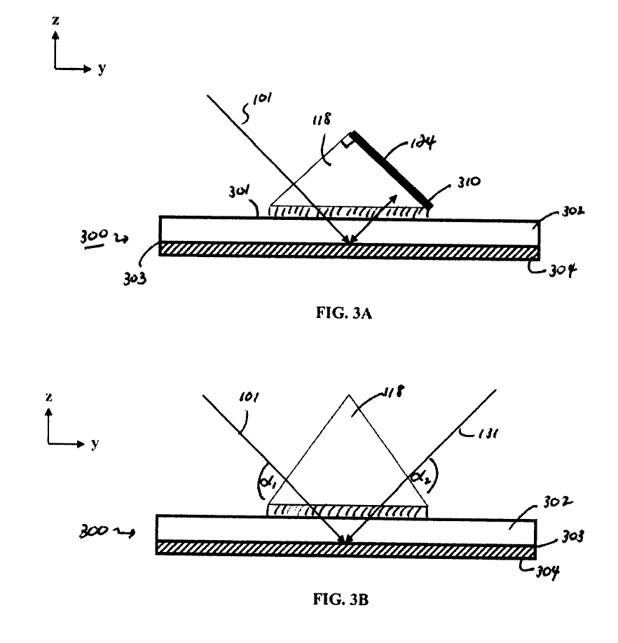

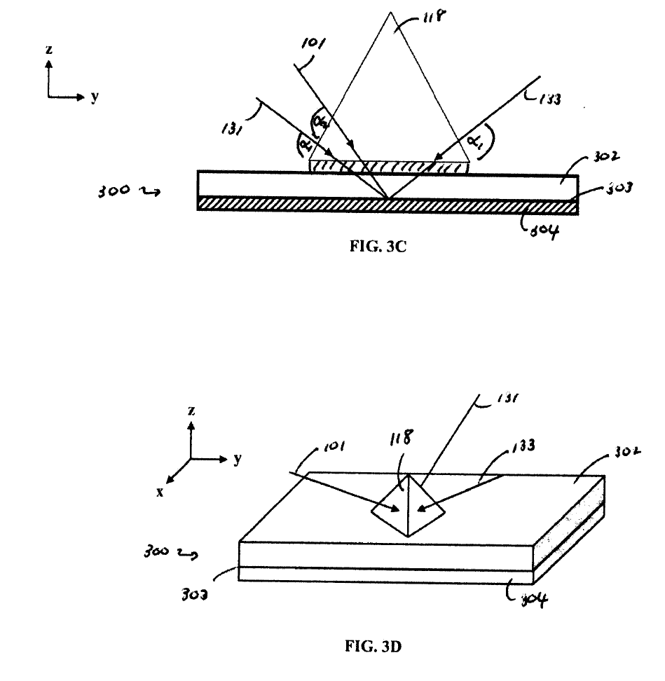

FIGS. 3A-3D show additional embodiments of apparatus for exposing a target 300 to radiation. Referring to FIG. 3A, an embodiment is shown in which target 300 includes a substrate layer 302 having a refractive index n₁ and a first layer 304 having a refractive index n₂ on a surface of substrate 302, where n₁>n₂. A coupling device 118 couples a beam of radiation 101 from either an optical source or optical elements to substrate 302. As shown in FIG. 3A, coupling device 118 is a 45°/45°/90° coupling prism. Coupling device 118 includes a bottom side that forms an interface 301 with substrate 302. Coupling device 118 is not limited to a 45°/45°/90°coupling prism, however, and can include other types of coupling devices, as described above.

To reduce reflections and optical loss at interface 301, prism coupler 118 has a refractive index nₚ that is close in value to the refractive index n₁ of substrate 302 and includes a layer 310 of an index-matching fluid at interface 301. As an example, prism coupler 118 can be formed from quartz having a refractive index of approximately 1.517 whereas substrate 302 can be formed from fused silica having a refractive index of approximately 1.46. An index matching fluid having a refractive index of about 1.49-1.52 can be placed between prism 118 and substrate 302. An example of an index matching fluid is top antireflection coating (TARC) material IOC-118 (which has a refractive index n=1.52 at 266 nm), commercially available from Shin-Etsu Chemical Co., Ltd. (Tokyo, JP). A further example of an index matching fluid is AZ Aquatar III TARC (n=1.49-1.52 at 266 nm), commercially available from AZ Electronic Materials USA Corp. (Branchburg, N.J.)

When incident radiation 101 impinges on interface 303 at an angle greater than the interface critical angle, it is totally internally reflected back towards prism coupler 118. Prism coupler 118 can include a reflective coating 124 that serves to reflect the radiation 101 back again towards interface 303. Reflective coating 124 can include any material that substantially reflects radiation having the same wavelength as radiation 101. Examples of reflective coating material can include metals such as gold, silver, or titanium. Other reflective coatings, such as multilayer dichroic mirrors, can be used as well.

As a result, both incident radiation 101 and radiation reflected from coating 124 impinge on interface 303. If there happens to be a phase difference between incident radiation 101 and the reflected radiation, then an interference pattern which is periodic in at least one dimension forms at interface 303. Accordingly, an evanescent field corresponding to the interference pattern will extend into first layer 304.

As before, first layer 304 can be formed from a photo-sensitive material, such as positive or negative photoresist. Thus, the evanescent field generated at interface 303 exposes the photo-sensitive material and transfers a mirror image (or a negative mirror image if a negative resist is used) of the interference pattern into layer 304. Layer 304 then can be developed or undergo further processing, as required. Thus, it is possible to form an interference profile in layer 304 using a single radiation source.

Referring to FIG. 3B, a further embodiment for exposing a target to radiation is shown. In this embodiment, two separate beams of radiation, each having a wavelength λ, are incident on a coupling prism 118 (e.g., a 60°/60°/60° coupling prism). A first beam 101 is directed towards a first side of prism 118 at an angle α_{c} whereas a second beam 131, is directed towards a second side of coupling prism 118 at an angle α₂. A user can select the first and second angles (α₁, α₂) such that each incident beam is totally internally reflected at interface 303 and that the relative angle between beams 101 and 131 at interface 303 provides an interference pattern having the desired period.

In some implementations, the incident angle α₁ is substantially equal to the angle α₂. Alternatively, the angle α₁ can differ from the angle α₂ as long as both beams are incident at approximately the same region of the interface 303 so that an interference pattern is generated. For the purposes of this disclosure, “approximately the same region” corresponds to a distance over which the centers of each beam are separated by no more than half a beam-width.

While the foregoing examples provide interference patterns formed from two, coherent beams, other implementations are also possible. For example, referring to FIG. 3C, three coherent beams can be used. In this embodiment, a first beam 101, a second beam 131 and a third beam 133 of coherent radiation, each having the same wavelength λ, are combined to produce either a one-dimensional or two-dimensional interference pattern (not shown) at interface 303 between substrate 302 and first layer 304. To generate the two-dimensional interference pattern, at least one of the radiation beams is directed towards coupling device 118 at a different plane of incidence from the other two beams. For example, second and third beams 131, 133 can be directed along the y-z plane towards a triangular shaped prism coupler 118 at a first angle α₁ whereas first beam 101 can be directed at an angle to the y-z plane toward prism coupler 118 at a second different angle α₂ with respect to the y-z plane such that all three beams coincide at approximately the same region of interface 303. First and second angles (α₁, α₂) are selected such that each incident beam is totally internally reflected at interface 303. The two-dimensional interference pattern generated by the overlapping beams produces a corresponding two-dimensional evanescent wave interference pattern that extends into second layer 304.

The foregoing configuration is not limited to radiation incident from three different directions or angles. For example, a fourth beam of radiation can be directed towards the coupling device at a third angle α₃ that is different from α₁ and α₂ such that a 4-beam interference pattern is generated at interface 303. Radiation incident from additional directions can be used, as well, to generate one or two-dimensional evanescent interference patterns at interface 303.

While FIG. 3C shows a three-beam configuration in which two beams are coincident on the same surface of prism coupler 188, configurations in which each beam is coincident on a different prism surface are also possible. For example, referring to FIG. 3D, three different beams (101, 131, 133) of coherent radiation, each having the same wavelength λ, are incident on coupling device 118, in which device 118 has a tetrahedron shape. Each incident beam is directed towards a different face of coupling device 118 and refracted towards the same approximate region of an interface 303 between substrate layer 302 and first layer 304 of target 300. The angles of incidence on the coupling device are selected such that each beam is totally internally reflected at target interface 303, The overlapping radiation gives rise to a two-dimensional interference pattern at the interface 303 and a corresponding evanescent wave interference pattern that extends into the second layer 304.

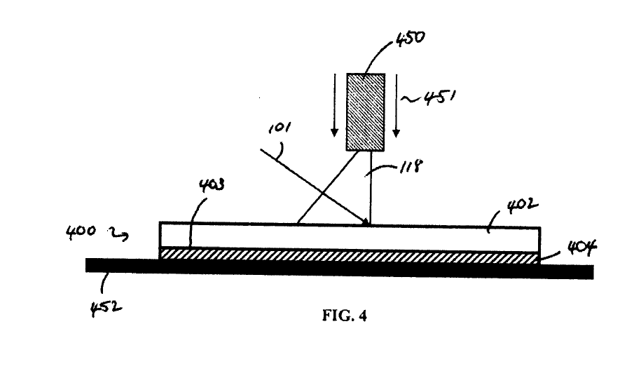

FIG. 4 illustrates an example of a mounting device 450 for mounting coupling device 118 to a target 400. Here, coupling device 118 is a coupling prism placed on the surface of a substrate layer 402 of target 400. Target 400 is supported by a substrate holder 452. Mounting device 450 is placed on the top surface of coupling device 118 and force is applied in a downward direction 451 to hold coupling device 118 in place on target 400. The downward force can be applied using, for example, a clamp or manually applied pressure. In some embodiments, an automated machine applies the downward pressure on the coupling device using, for example, a automated actuator.

When an index matching fluid is used, any bubbles should be removed between coupling device 118 and target 400 as the bubbles and resulting air pockets can lead to unwanted diffraction, refraction and loss of incident light. For example, the bubbles can be removed by degassing the fluid prior to applying it to the prism. Alternatively, or additionally, exposure can be carried out in a low pressure environment.

In some embodiments, coupling device 118 may be mounted on target 400 using gravity. Alternatively, or in addition, coupling device 118 can be mounted by means of a suction force between device 118 and target 400.

In general, the direction of the incident radiation in the foregoing examples can be modified by altering the position/orientation of the light sources or by changing the position/orientation of the target. For example, FIG. 5 illustrates coupling device 118 and target 500 on a moveable substrate holder 508. One or more motors 510 attached to substrate holder 508 provide translation and/or rotation of holder 508 along the x, y and/or z-axis. A processor 512 coupled to motor 510 sends control signals to the motor that specify the direction and speed in which motor 510 moves substrate holder 508. By altering the position/orientation of substrate holder 508, and hence target 500, the position and effective angle of incidence of the incoming radiation relative to coupling device 118 can be changed.

Processor 512 can be incorporated into any apparatus, device, or machine for processing data and outputting control signals to motor 510, including by way of example one or more servers, desktop computers, or laptop computers. To provide for interaction and control of the processor and, hence, motor 510, a user may interface with the processor through a display device (e.g., a cathode ray tube or liquid crystal display monitor), a keyboard, and a pointing device (e.g., a mouse or a trackball), by which the user can provide input.

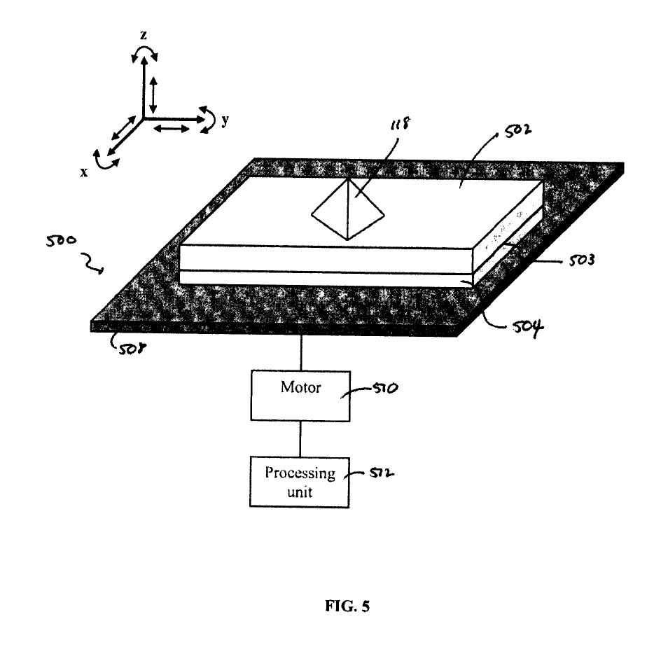

An advantage of having a movable substrate holder is that, in some implementations, patterns having features varying in two dimensions can be formed in photo-sensitive material using a single radiation source. For example, FIG. 6 illustrates a process flow, using moveable substrate holder 508 of FIG. 5, for forming a pattern having features varying in two dimensions in a photo-sensitive layer using a single radiation source. Radiation from an optical source is directed (601) towards a coupling device 118 that is in contact with a target 500 having both a substrate layer 502 and a first photo-sensitive layer 504. Once the radiation is coupled into substrate layer 502, a user can modify (603) the location and inclination of substrate holder 508 to ensure that the incident radiation is totally internally reflected at an interface 503 between substrate layer 502 and photo-sensitive layer 504. For example, the user can enter rotation and translation coordinates into a computer connected to motor 510. A processor 512 within the computer sends electronic rotation and translation control signals to the motor in accordance with the coordinates entered by the user.

For example, substrate holder 508 can be rotated around the x-axis, the y-axis or the z-axis individually or in combination (e.g., rotated by 30°, 90°, 120°, 180°, 240°, 300° or 330°) to a first position. In some cases, substrate holder 508 can be translated along the x-axis, the y-axis or the z-axis individually or in combination. To prevent inadvertent exposure, the optical source can be turned off until the desired position of the substrate holder is reached. Once substrate holder 508 has moved to the first position, an evanescent field generated by total internal reflection exposes (605) photo-sensitive layer 504.

A user then can reposition (607) substrate holder 508 to a second different location by entering new coordinates. For example, substrate holder 508 can be rotated by 90° around the z-axis. If a tetrahedron prism is used as coupling device 118, it is possible to maintain total internal reflection at interface 503. Thus, photo-sensitive layer 504 can again be exposed (609) to the evanescent field. However, the evanescent field will have been rotated by 900. Accordingly, by exposing photo-sensitive layer 504 to the evanescent field along two orthogonal directions, a crossing pattern having features varying in two dimensions (e.g., along the y-axis and along the x-axis) can be formed in photo-sensitive layer 504.

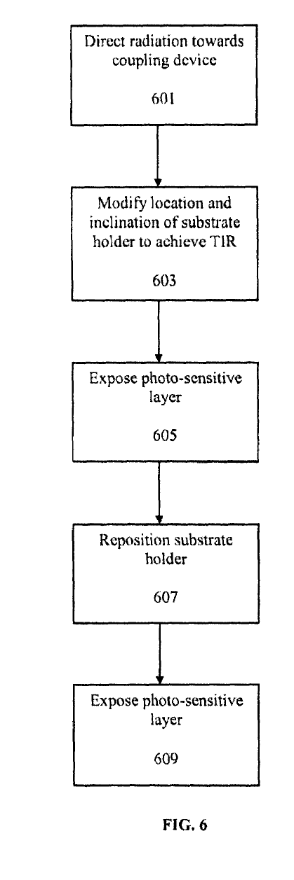

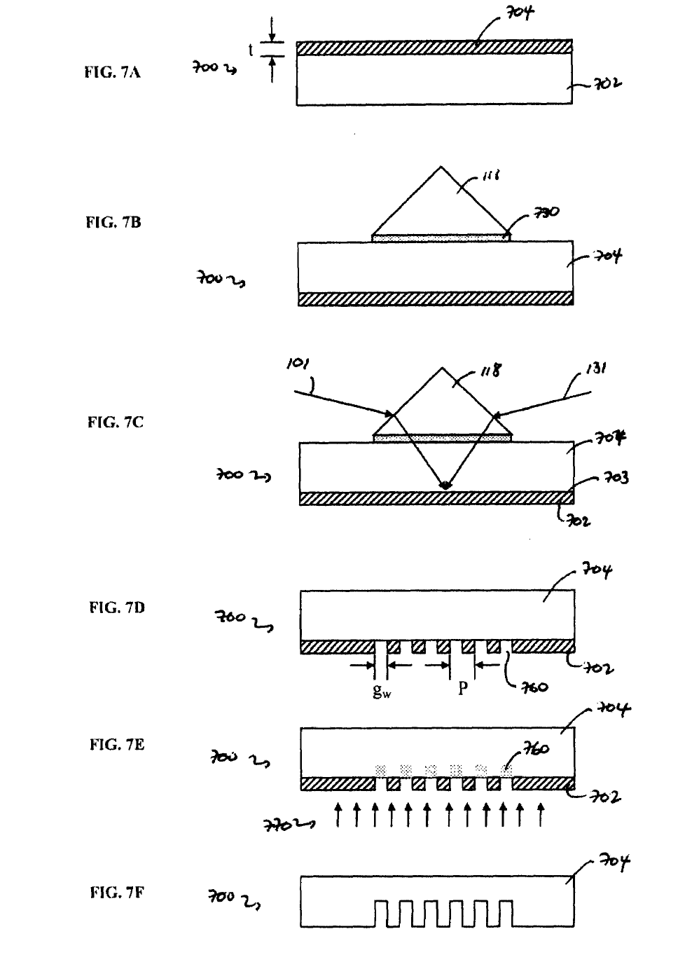

FIGS. 7A-7F illustrate an example photolithography process, in which an evanescent field is used to expose a photo-sensitive material. Referring to FIG. 7A, a fused silica substrate 702 is provided. Substrate 702 is not limited to fused silica and can include materials such as glass, sapphire, silicon, or quartz, among others. Substrate 702 then is coated with a positive or negative photoresist first layer 704 to a thickness, t, e.g., of about 125 nm using spin-coating. Once the resist is applied to substrate 702, the device is baked to drive off solvents. Other photo-sensitive polymers, deposition techniques and coating thicknesses can be used as well. As an example, in some embodiments, the photoresist AZ7900 (commercially available from AZ Electronic Materials USA Corp., Branchburg, N.J.) can be used (e.g., used as-is or reformulated as necessary). This resist can be spin-coated (e.g., . Speed/Ramp=˜4500/1500 RPM) and baked (e.g., Bake Temp/Time=90C/90 seconds) to provide a resist layer having a thickness of about 165 nm to 175nm with a refractive index n=1.63 at 633 nm.

In some embodiments, first layer 704 can be formed from a combination of a photoresist layer and an anti-reflection coating (ARC) polymer layer. For example, in some embodiments, first layer 704 is formed using a resist along with an ARC layer such as XHRiC-11, commercially available from Brewer Science, Inc. (Rolla, Mo.) An advantage of applying the ARC polymer layer is that it can be used to suppress the evanescent field once it has passed through the photoresist layer.

Referring to FIG. 7B, coupling device 118, such as a coupling prism, then is mounted to substrate 702. Prior to mounting the coupling device 118, an index matching fluid 730, such as those fluids mentioned above, is typically applied to a bottom surface of coupling device 118 so that reflections at the interface between coupling device 118 and substrate 702 are minimized. Referring to FIG. 7C, radiation having a wavelength λ from a first beam 101 and radiation, also having wavelength λ, from a second beam 131 are directed towards coupling device 118. First beam 101 and second beam 131 are coupled into the substrate 702 and totally internally reflected at approximately the same point along an interface 703 between substrate 702 and first layer 704 to create an evanescent wave interference pattern that decays into second layer 704. The evanescent wave pattern generated by the reflection of the first and second beams thus exposes the photoresist of first layer 704.

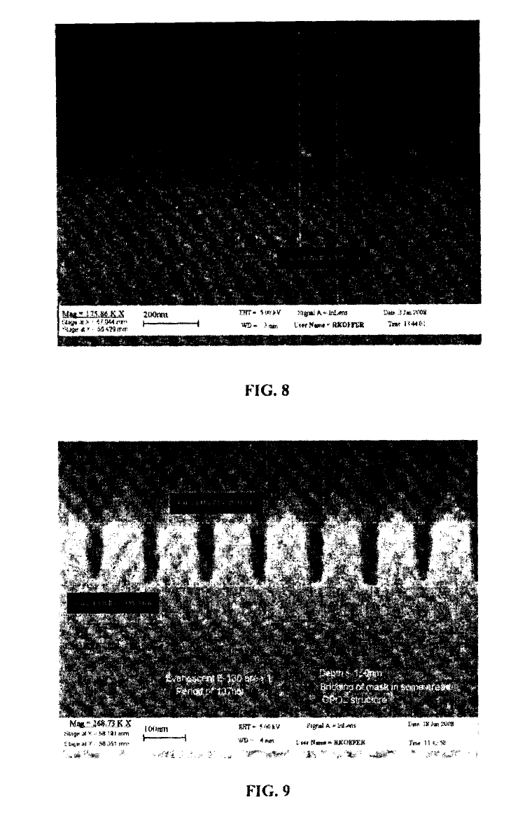

After exposure, the target 700 then is post baked and first layer 704 is developed using tetramethylammonium hydroxide (TMAH), or other developers as known in the art, to produce grating pattern 760 as shown in FIG. 7D. Grating pattern 760 includes a plurality of equally spaced grooves, each groove having a width g_{w} and a periodicity P. An example of a grating pattern formed in a photoresist layer by evanescent wave exposure is shown in FIG. 8. The period of the grating pattern shown in the example of FIG. 8 is approximately 135 nm.

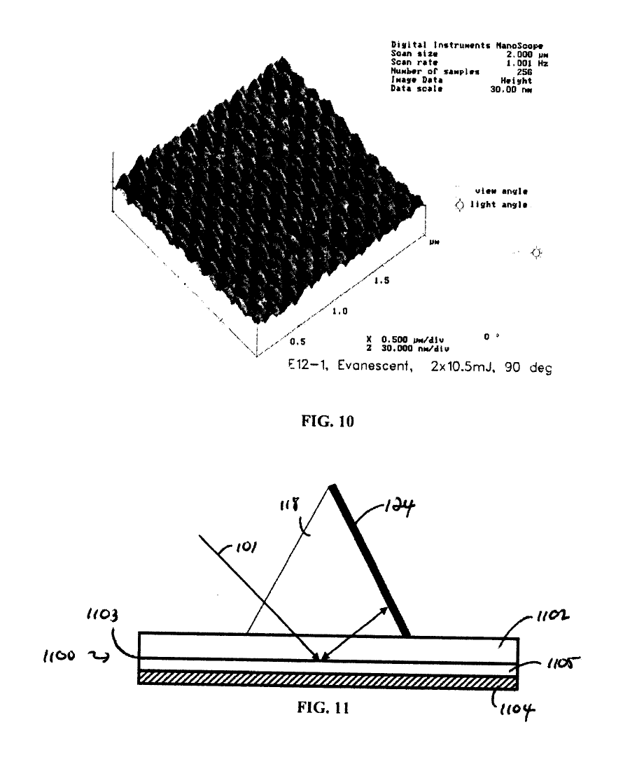

Subsequent to development, grating pattern 760 can be transferred to substrate 702 by exposing portions of substrate 702, which are not covered with photoresist, to an etch process 770, as shown in FIG. 7E. The etch process can include, for example, a dry etch process (e.g., reactive ion etch or plasma etch) or a wet etch process as known in the art. Depending on the resist thickness and etch time, grating pattern 760 is transferred either through the entire substrate 702 or only partially through substrate 702, as shown in FIG. 7F. In some cases, an optional metal mask may be deposited on the patterned photoresist grating pattern 760 to enable deep etching of substrate 702. For example, in some implementations a chrome mask may be deposited on first layer 704 using deposition techniques such as evaporation or sputtering. In some cases, the deposition can be an angled deposition so that the exposed surface of substrate 702 is in the shadow of the deposition and is not covered by the deposit. Accordingly, grating pattern 760 of the first layer 704 can be protected during prolonged etching of substrate 702. After grating pattern 760 has been transferred to substrate 702, the metal mask and/or photoresist layer can be removed using standard etching solutions and techniques as known in the art. An example of a grating pattern in a fused silica substrate formed using the foregoing process is shown in FIG. 9. The period of the grating pattern in the example is approximately 137 nm whereas the groove depth is about 150 nm. An example of a crossing grating pattern formed by exposing a photoresist to an evanescent wave interference pattern is shown in FIG. 10.

Although only two layers are described in the above targets (i.e., a substrate and a photo-sensitive layer), additional layers can be included as well. For example, in some embodiments, the photosensitive layer can be separated from the substrate by a third intermediary layer. In general, such intermediate layers should be transparent. Examples include dielectric materials such as hafnium oxide, silicon oxide, titanium oxide, aluminum oxide or others. Generally, intermediate layers can be used for a variety of purposes, such as, e.g., for an underneath ARC, to become the grating material, and/or to change the index of the surface touching the grating or other reason. As an example, a multi-layer structure can be composed of a resist on a silicon oxide layer, which is on a hafnium oxide layer, which is on the substrate. Here, hafnium oxide is used as an etch stop and the silicon oxide is used for the grating material. As another example, ARC layers can be provided using one or more layers of hafnium oxide, silicon oxide, and/or magnesium fluoride.

For example, FIG. 11 shows an embodiment for exposing a target 1100, in which target 1100 includes a second layer 1105, having a refractive index n₃, between a substrate 1102 of refractive index n₁ and a first layer 1104 of refractive index n₂. Each of the substrate, first and second layers can include a material that is able to transmit light having the same wavelength as source radiation 101. As in previous embodiments, first layer 1104 can include a photo-sensitive material such as photoresist or a photo-definable polymer. It is not necessary, however, that the refractive index n₂ of first layer 1104 be less than the refractive index n₁ of substrate 1102. Instead, if n₃<n₁, n₂, and first layer 1104 is within several wavelengths from substrate 1102 (in which a wavelength is defined by the source radiation 101), it is possible to pass energy from substrate 1102 into first layer 1104.

That is, source radiation 101 is coupled into substrate 1102 using a coupling device 118 such as a coupling prism. Radiation 101 is totally internally reflected at interface 1103 between substrate 1102 and second layer 1105 and directed towards a reflective coating 124 formed on coupling device 118. Light reflected back from coating 124 combines with incident radiation 101 at interface 1103 and generates an evanescent field (not shown). This evanescent field decays into the second layer 1105 and then couples energy from substrate 1102 into first layer 1104 (i.e., evanescent coupling), thus exposing the photo-sensitive first layer 1104. The exposed layer then can be developed and a pattern can be transferred to second layer 1105 using standard dry or wet etching techniques.

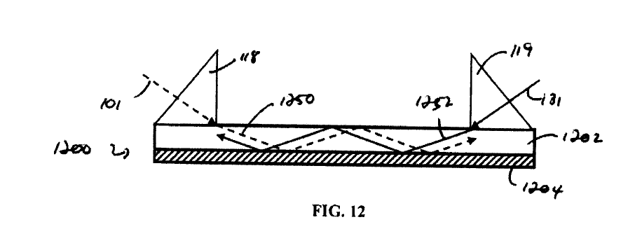

In some embodiments, two or more coupling devices can be used. For example, FIG. 12 illustrates two separate prism couplers (first coupling device 118 and a second coupling device 119) mounted on a target 1200 for respectively coupling a first beam 101 having a wavelength λ and a second beam 131 of radiation also having wavelength λ. As illustrated in FIG. 12, the two prism couplers, 118 and 119, are spaced apart from each other and radiation 101 and 131 experiences total internal reflection at both surfaces of substrate 1202, and is waveguided through at least a portion of substrate 1202. Thus, substrate 1202 serves as a waveguide along which a first guided wave 1250 and a second guided wave 1252 travel.

An interference pattern can be produced in substrate 1202 when first guided wave 1250 interacts with second guide wave 1252. This interference pattern his its own evanescent wave (not shown) that subsequently extends into first layer 1204. Thus, the interference pattern is transferred into first layer 1204 by means of evanescent wave exposure. A grating pattern then can be produced in substrate 1202 using standard developing and etching methods as known in the art. A distance L between each coupling device defines the length over which the transferred pattern extends. Therefore, by using two or more coupling devices, a user has greater control over the area to which the pattern is transferred.

A number of embodiments have been described. Other embodiments are within the scope of the claims.

What is claimed is:

1. A method, comprising:
providing an article, comprising:
a substrate;
a first layer supported by the substrate; and
an interface between the substrate and the first layer, wherein the substrate is substantially transparent to radiation at a wavelength λ and the first layer being formed from a photoresist; and
exposing the first layer to radiation by directing radiation at λ through the substrate to impinge on the interface so that the radiation experiences total internal reflection at the interface.

2. The method of claim 1, wherein the radiation forms an intensity pattern at the interface.

3. The method of claim 2, wherein the intensity pattern is an interference pattern.

4. The method of claim 3, wherein the interference pattern is formed by directing a first part of the radiation and a second part of the radiation along different paths to overlap at the interface.

5. The method of claim 4, wherein the different paths each impinge on the interface once.

6. The method of claim 4, wherein the first part impinges on the interface twice.

7. The method of claim 4, wherein the interference pattern is formed by directing a third part of the radiation to overlap with the first and second parts of the radiation at the interface, wherein the third part is directed along a different path to the first and second parts.

8. The method of claim 2, wherein exposing the first layer to radiation comprises exposing the layer to the radiation a first time with a first relative orientation between the first layer and the intensity pattern and exposing the layer to the radiation a second time with a second relative orientation between the first layer and the intensity pattern, the first and second relative orientations being different.

9. The method of claim 8 further comprising rotating the article prior to exposing the layer to the radiation a second time.

10. The method of claim 2, wherein the intensity pattern is periodic in at least one dimension.

11. The method of claim 10, wherein the intensity pattern has a period of about 120 nm or less in the at least one dimension.

12. The method of claim 1, wherein the radiation is directed to impinge on the interface at an angle of incidence that is equal to or greater than the critical angle.

13. The method of claim 1, wherein directing the radiation through the substrate comprises directing the radiation through a prism.

14. The method of claim 13, wherein the prism is optically coupled to the substrate.

15. The method of claim 13, wherein the article further comprises an index matching fluid between the prism and the substrate.

16. The method of claim 1, wherein the radiation is substantially collimated while propagating through the substrate.

17. The method of claim 1, wherein λ is about 300 nm or less.

18. The method of claim 1, wherein λ is 193 nm, 242 nm, 266 nm, 351 nm, 512 nm, or 1,032 nm.

19. The method of claim 1, wherein the substrate has a refractive index, nₛ, and the photoresist has a refractive index, nᵣ, and nₛ>nᵣ at λ.

20. The method of claim 1, wherein the interface is the interface between the substrate and the photoresist of the first layer.

21. The method of claim 1, further comprising forming a pattern in the substrate after exposing the first layer.

22. The method of claim 21, wherein forming the pattern comprises developing the photoresist after exposing the first layer.

23. The method of claim 22, wherein forming the patterning comprises etching the substrate after developing the photoresist.

24. A method, comprising:
providing an article comprising a substrate and a first layer supported by the substrate, the substrate being substantially transparent to radiation at a wavelength λ and the first layer comprising a photoresist; and
exposing the first layer to evanescent radiation by directing radiation at λ through the substrate.

25. A process for manufacturing a grating pattern comprising:
providing a first layer in contact with a second layer;
exposing the second layer to an evanescent interference pattern,
wherein exposing the second layer comprises directing radiation at wavelength λ towards an interface between the first layer and the second layer such that the radiation is totally internally reflected at the interface; and
removing the exposed portions or unexposed portions of the second layer to form the grating pattern.
